(19) United States
(12) Patent Application Publication
(10) Pub. No.: US 2016/0351415 A1
(43) Pub. Date: Dec. 1, 2016

(54) SEMICONDUCTOR SUBSTRATE FOR FLASH LAMP ANNEAL, ANNEAL SUBSTRATE, SEMICONDUCTOR DEVICE, AND METHOD FOR MANUFACTURING SEMICONDUCTOR DEVICE

(71) Applicant: Shin-Etsu Handotai Co., Ltd., Tokyo (JP)

(72) Inventors: Tsuyoshi OHTSUKI, Annaka (JP); Hiroshi TAKENO, Annaka (JP)

(73) Assignee: SHIN-ETSU HANDOTAI CO., LTD., Tokyo (JP)

(21) Appl. No.: 15/117,269

(22) PCT Filed: Jan. 26, 2015
(86) PCT No.: PCT/JP2015/000319

§ 371 Date: Aug. 8, 2016

(30) Foreign Application Priority Data
Feb. 26, 2014 (JP) 2014-035156

(51) Int. Cl. H01L 21/324; H01L 29/36; H01L 29/32; H01L 21/265; H01L 21/268

(52) U.S. Cl. CPC H01L 21/3242; H01L 21/265; H01L 21/2686; H01L 29/32; H01L 29/36

(57) ABSTRACT

A semiconductor substrate for flash lamp anneal is used in a manufacturing process of performing ion implantation to form a p-n junction on a semiconductor substrate surface and recovering an ion implantation defect by the flash lamp anneal, carbon concentration of the semiconductor substrate being 0.5 ppma or less. Consequently, it is possible to provide the semiconductor substrate for flash lamp anneal which can easily and surely prevent the ion implantation defect from remaining in a device using a flash lamp anneal process.

### BACKGROUND OF THE INVENTION

1. Field of the Invention

The present invention relates to a semiconductor substrate for flash lamp anneal for use in a device manufacturing process including a process of forming an impurity diffusion layer on a semiconductor substrate surface, an anneal substrate subjected to the process of forming the impurity diffusion layer on the semiconductor substrate surface, a semiconductor device fabricated using these substrates, and a method for manufacturing a semiconductor device including the device manufacturing process including the process of forming the impurity diffusion layer on the semiconductor substrate surface.

2. Description of the Related Art

Miniaturization has advanced to improve LSI performance, and a gate length of transistors have been reduced. With a reduction in gate length, a depth of a diffusion layer in a source/drain region must be shallowed. For example, in case of a device (a transistor) having a gate length of approximately 30 nm, a very shallow diffusion depth of approximately 15 nm is required as a diffusion depth of a source/drain portion.

To form such a diffusion layer, ion implantation has been conventionally adopted, and a method for implanting, e.g., B⁺ or BF₂⁺⁺ with very low acceleration of 0.2 to 0.5 keV has been used. However, an ion-implanted atom cannot lower resistance at it is. Further, in an ion-implanted region, a point defect such as interstitial silicon or an atomic vacancy is produced in a silicon substrate.

Thus, after the ion implantation, anneal is performed for activation of atoms (decreasing resistance) and recovery of the defect, but the ion-implanted atoms are diffused and an impurity distribution spreads due to this anneal. Further, there is also known a phenomenon that the impurity diffusion is accelerated due to not only the anneal but also the point defect caused by the ion implantation.

To enable formation of a shallow junction which has a depth of 15 nm or less and a width of 10 nm or less in a transverse direction immediately below an ion implantation mask even though the spread due to the diffusion is taken into consideration, an anneal method for irradiating high energy in a very short time has been examined and adopted (see, e.g., Patent Literatures 1 and 2).

As this anneal method, there is, e.g., anneal using a flash lamp having a rare gas such as xenon enclosed therein. This lamp is used in a method for irradiating high energy of several tens of J/cm² or more as pulse light of 0.1 to 100 milliseconds. Thus, an impurity distribution formed by the ion implantation can be activated without substantial change.

However, since this high energy is used, it can be considered that thermal stress in a silicon substrate becomes considerable and damage such as cracks or slips of the silicon substrate is caused, and examinations for this actually have been conducted.

For example, Patent Literature 3 discloses that, to form a shallow impurity diffusion region without causing damage in a semiconductor substrate, materials having a material which functions as an acceptor or a donor to the semiconductor substrate and a material which does not function as an acceptor or a donor to the semiconductor substrate are implanted into the semiconductor substrate.

### CITATION LIST

### Patent Literatures

Patent Literature 1: Japanese Unexamined Patent Application Publication (Kokai) No. 2002-198322

Patent Literature 2: Japanese Unexamined Patent Application Publication (Kokai) No. 2005-347704

Patent Literature 3: Japanese Unexamined Patent Application Publication (Kokai) No. 2009-027027

### SUMMARY OF THE INVENTION

### Problem to be Solved by the Invention

However, in a technology disclosed in Patent Literature 3, a plurality of ion species must be implanted, and there arises a problem that processes become complicated. Further, the technology disclosed in Patent Literature 3 solves damage such as cracks or slips of the silicon substrate, but there is still room for further improvement in terms of preventing ion implantation defects from remaining.

In view of the problem, it is a purpose of the present invention to provide a semiconductor substrate for flash lamp anneal, an anneal substrate, a semiconductor device, and a method for manufacturing a semiconductor device which can easily and surely prevent ion implantation defects from remaining in a device used in a flash lamp anneal process.

### Means for Solving Problem

To achieve the purpose, the present invention provides a semiconductor substrate for flash lamp anneal which is used in a manufacturing process of performing ion implantation to form a p-n junction on a semiconductor substrate surface and recovering an ion implantation defect by the flash lamp anneal, carbon concentration of the semiconductor substrate being 0.5 ppma or less.

As described above, according to the semiconductor having the carbon concentration of 0.5 ppma or less, when the manufacturing process of performing the ion implantation to form the p-n junction on the semiconductor substrate surface and recovering the ion implantation defect by the flash lamp anneal is used, the ion implantation defect can be easily and surely prevented from remaining.

At this time, the semiconductor substrate can be made of silicon.

The present invention can be preferably applied to such a semiconductor substrate for flash lamp anneal made of silicon.

Furthermore, the present invention provides a semiconductor device, the semiconductor device being fabricated with the use of the above semiconductor substrate for flash lamp anneal.

According to the semiconductor device fabricated with the use of the semiconductor substrate for flash lamp anneal of the present invention, the ion implantation defect formed at the time of forming the p-n junction on the semiconductor substrate surface can be easily and surely prevented from remaining, and the semiconductor device having a high performance that can acquire a high yield rate can be provided.

Moreover, the present invention provides an anneal substrate in which a p-n junction is formed on a semiconductor substrate surface by performing ion implantation, and an ion implantation defect is recovered by flash lamp anneal, the anneal substrate having the p-n junction on the substrate surface and carbon concentration of 0.5 ppma or less.

As described above, according to the anneal substrate having the carbon concentration of 0.5 ppma or less, the ion implantation defect at the time of forming the p-n junction on the semiconductor substrate surface can be easily and surely prevented from remaining.

At this time, the anneal substrate can be made of silicon.

The present invention can be preferably applied to such an anneal substrate made of silicon.

Additionally, the present invention provides a semiconductor device, the semiconductor device being fabricated with the use of the above anneal substrate.

According to the semiconductor device fabricated with the use of the semiconductor substrate for flash lamp anneal of the present invention, the ion implantation defect on the semiconductor substrate surface formed at the time of forming the p-n junction can be easily and surely prevented from remaining, and the semiconductor device having a high performance that can acquire a high yield rate can be provided.

Further, the present invention provides a method for manufacturing a semiconductor device including a process of forming a p-n junction on a semiconductor substrate surface, which is a step of performing ion implantation and then performing flash lamp anneal to recover an ion implantation defect, wherein the anneal is performed with the use of a semiconductor substrate having carbon concentration of 0.5 ppma or less.

As described above, when the flash lamp anneal after the ion implantation is performed with the use of the semiconductor substrate having the carbon concentration of 0.5 ppma or less, the ion implantation defect on the semiconductor substrate surface formed at the time of forming the p-n junction can be easily and surely prevented from remaining.

### Effect of the Invention

As described above, according to the present invention, when the flash lamp anneal is used as the anneal after the ion implantation, the ion implantation defect on the semiconductor substrate surface formed at the time of forming the p-n junction can be easily and surely prevented from remaining, and a high yield rate can be provided.

### BRIEF DESCRIPTION OF DRAWINGS

FIG. 1 is a view showing differences in CL spectrum depending on carbon concentration; and

FIG. 2 is a view showing a relationship between maximum intensity of a broad emission spectrum of CL and carbon concentration.

### DETAILED DESCRIPTION OF THE PREFERRED EMBODIMENTS

As described above, with miniaturization for high LSI performance, a depth of a diffusion layer in a source/drain region must be reduced, and an anneal method (flash lamp anneal) for irradiating high energy in a very short time has been examined and adopted so as to enable formation of a shallow junction.

As this anneal method, there is, e.g., anneal using a flash lamp having a rare gas such as xenon enclosed therein, but the flash lamp anneal is not restricted thereto, and anneal which irradiates high-energy in a very short time can suffice.

Since this anneal method uses the high energy, it can be considered that thermal stress in a silicon substrate increases and damage such as cracks or slips of the silicon substrate is caused, and an examination for this has been actually conducted.

However, in terms of preventing ion implantation defects from remaining, there is still room for further improvement.

Thus, the present inventors have repeatedly conducted keen examinations on a semiconductor substrate for flash lamp anneal which can easily and surely prevent an ion implantation defect from remaining in a device using the flash lamp anneal process.

The present inventors have focused on point defect behavior instead of a standpoint such as cracks or slips of the silicon substrate, and found out that the ion implantation defect can be easily and surely prevented from remaining by adopting a semiconductor substrate whose carbon concentration is 0.5 ppma or less when using a manufacturing process of performing ion implantation to form a p-n junction on a semiconductor substrate surface and recovering an ion implantation defect by the flash lamp anneal, thus bringing the present invention to completion.

The present invention will now be described as an embodiment hereinafter in detail with reference to the drawings, but the present invention is not restricted thereto.

First, a semiconductor substrate for flash lamp anneal according to the present invention will now be described.

The semiconductor substrate for flash lamp anneal according to the present invention is configured to be used in a manufacturing process of performing ion implantation to form p-n junctions on a semiconductor substrate surface and recovering an ion implantation defect by the flash lamp anneal, and carbon concentration in the semiconductor substrate is 0.5 ppma or less.

As described above, when the semiconductor substrate having the carbon concentration of 0.5 ppma or less is used in the manufacturing process of performing the ion implantation to form the p-n junctions on the semiconductor substrate surface and recovering the ion implantation defect by the flash lamp anneal, the ion implantation defect can be easily and surely prevented from remaining.

In this case, the semiconductor substrate for flash lamp anneal can be made of silicon.

The present invention can be preferably applied to such a semiconductor substrate for flash lamp anneal made of silicon.

Next, an anneal substrate according to the present invention will now be described.

The anneal substrate according to the present invention is subjected to the ion implantation to form the p-n junctions on the semiconductor substrate surface and also subjected to the flash lamp anneal to recover the ion implantation defect, the anneal substrate has the p-n junctions on the substrate surface and carbon concentration which is 0.5 ppma or less.

As described above, according to the anneal substrate having the carbon concentration of 0.5 ppma or less, the ion implantation defect on the semiconductor substrate surface formed at the time of forming the p-n junctions can be easily and surely prevented from remaining.

In this case, the anneal substrate can be made of silicon.

The present invention can be preferably applied to such an anneal substrate made of silicon.

Next, a semiconductor device according to the present invention will now be described.

The semiconductor device according to the present invention is a semiconductor device fabricated by using the above semiconductor substrate for flash lamp anneal or the above anneal substrate.

According to the semiconductor device fabricated by using the semiconductor substrate for flash lamp anneal of the present invention or the anneal substrate of the present invention, the ion implantation defect on the semiconductor substrate surface formed at the time of forming the p-n junctions can be surely prevented from remaining, and the semiconductor device having a high performance that can acquire a high yield rate can be provided.

Next, a method for manufacturing a semiconductor device according to the present invention will now be described.

The method for manufacturing a semiconductor device of the present invention includes a process of forming a p-n junction on a semiconductor substrate surface, which is a process of performing the ion implantation and then conducting the flash lamp anneal to recovery an ion implantation defect, and the anneal is performed with the use of the semiconductor substrate having the carbon concentration of 0.5 ppma or less.

When the flash lamp anneal after the ion implantation is performed with the use of the semiconductor substrate having the carbon concentration of 0.5 ppma or less, the ion implantation defect on the semiconductor substrate surface formed at the time of forming the p-n junction can be easily and surely prevented from remaining.

### Experimental Example

A single-crystal silicon wafer having low carbon concentration (carbon concentration: 0.05 ppma) and a single-crystal silicon wafer having high carbon concentration (carbon concentration: 1 ppma) were prepared, and boron was implanted into them. Point defects were formed in silicon substrates by this ion implantation.

Then, the flash lamp anneal was performed for recovery of the defects caused by the ion implantation and activation, and recovery conditions of the defects caused by the ion implantation were investigated.

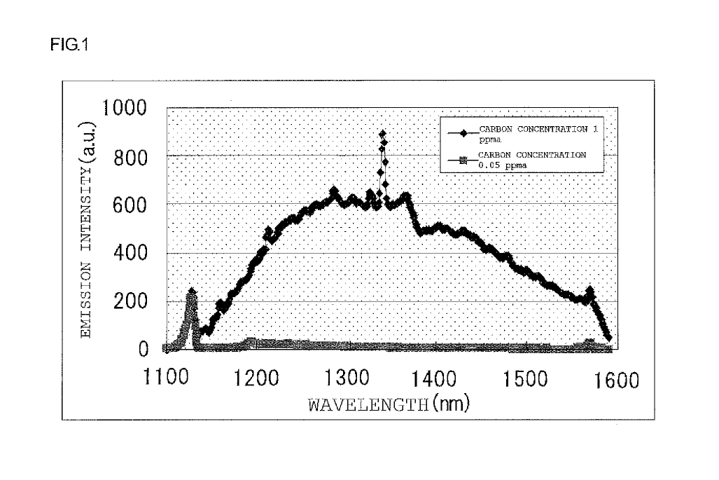

In an evaluation by observation using a transmission electron microscope (which will be referred to as a TEM hereinafter), no defect was observed on any level in ion-implanted regions. On the other hand, in an evaluation using cathode luminescence (which will be referred to as CL hereinafter), broad characteristic light emission was observed in the single-crystal silicon wafer having the high carbon concentration, but nothing was observed expect for a TO line (corresponding to a peak having a wavelength of approximately 1120 nm) caused due to band edge emission of silicon in the silicon substrate having the low carbon concentration (see FIG. 1).

It can be considered that a difference in detection sensitivity between the evaluation by the TEM observation and the evaluation using the CL is produced for the following reason. That is, the TEM has a narrow observation region and is hard to capture the point defects as images and, on the other hand, the CL has a large observation region (especially in a depth direction) since a scanning electron microscope (SEM) is used and also has high sensitivity by detecting a luminescence center at a deep level in principle.

Further, the evaluation using the CL was likewise carried out to silicon substrates having carbon concentrations of 0.1 ppma, 0.2 ppma, 0.4 ppma, 0.5 ppma, 0.6 ppma, 0.7 ppma, and 0.8 ppma, respectively.

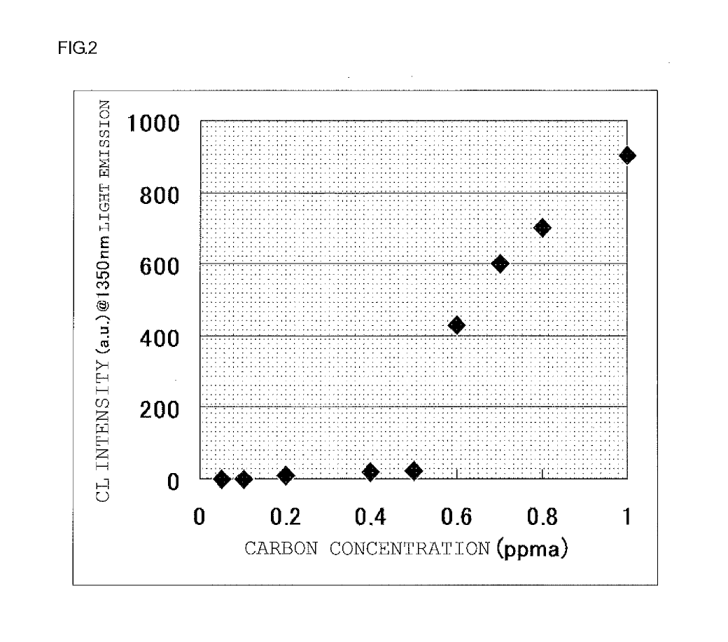

FIG. 2 is a view showing a relationship between maximum intensity of a broad emission spectrum of the CL and the carbon concentration of each substrate.

As can be understood from FIG. 2, if the carbon concentration is 0.5 ppma or less, no CL emission is performed, i.e., the defects caused by the ion implantation are recovered.

The following can be considered as a reason why the remains of the ion implantation defects is reduced when the carbon concentration in the substrate is lowered. That is, since the carbon has a relatively small atomic radius and there is a distortion at a position where the carbon is present, interstitial silicon produced by the ion implantation easily gathers. Thus, if the carbon concentration in the substrate is lowered regions where the interstitial silicon easily gathers is reduced, and hence the remains of the ion implantation defects is reduced.

Further, the following can be considered as a reason why the broad characteristic emission is observed when the ion implantation defects remain. That is, when the flash lamp anneal is performed, the situation is as if a reaction of recovering the ion implantation defects is quenched halfway through, and a complicated CL spectrum is shown.

### EXAMPLES

The present invention will now be more specifically described with reference to examples and a comparative example, but the present invention is not restricted thereto.

### Example 1

As a sample, a single-crystal silicon wafer sliced out from a p-type silicon single crystal with a diameter of 200 mm manufactured by doping boron alone using a polycrystalline raw material and a high-purity quartz crucible, was used. A resistivity of this single-crystal silicon wafer was 10 Ω·cm, and carbon concentration of the same was 0.05 ppma.

This wafer was subjected to the ion implantation using 5×10¹³ atoms/cm² of boron at 10 keV, and then a preheating was performed at 500° C. and the flash lamp anneal using a xenon lamp as a light source was performed under conditions of irradiation energy of 22 J/cm², an irradiation time of 1.4 millisecond, and an irradiation temperature of 1200° C. Then, ion implantation defects were evaluated using the CL, and nothing was observed except for a TO line produced due to a band edge emission of silicon as shown in FIG. 1.

The same substrate was prepared, oxidation for a thickness of 300 nm was performed in a Pyro (water vapor) atmosphere at 1000° C., and photolithography was further carried out to open a window in an oxide film. It is to be noted that wet etching using a hydrofluoric acid was used as oxide film etching after the photolithography.

Subsequently, this wafer was subjected to the ion implantation using 5×10¹³ atoms/cm² of boron at 10 keV and further subjected to the ion implantation using 5×10¹⁴ atoms/cm² of phosphorous at 3 keV, and then a preheating was performed at 500° C. and the flash lamp anneal using a xenon lamp as a light source was performed under conditions of irradiation energy of 22 J/cm², an irradiation time of 1.4 millisecond, and an irradiation temperature of 1200° C. to form the p-n junctions.

An area of each p-n junction was set to 4 mm². A reverse direction leakage current value measured at each p-n junction was 15 pA.

### Example 2

As a sample, a single-crystal silicon wafer sliced out from a silicon single crystal manufactured by doping boron and a small amount of carbon was used. Carbon concentration of the single-crystal silicon wafer at this time was 0.5 ppma.

This wafer was subjected to the ion implantation using 5×10¹³ atoms/cm² of boron at 10 keV, and then a preheating was performed at 500° C. and the flash lamp anneal using a xenon lamp as a light source was performed under conditions of irradiation energy of 22 J/cm², an irradiation time of 1.4 millisecond, and an irradiation temperature of 1200° C. Then, ion implantation defects were evaluated using CL, and nothing was observed except for a TO line produced due to a band edge emission of silicon like the level of the carbon concentration of 0.05 ppma shown in FIG. 1.

The same substrate was prepared, and p-n junctions were formed like Example 1.

An area of each p-n junction was set to 4 mm². A reverse direction leakage current value measured at each p-n junction was 15 pA.

### Comparative Example 1

As a sample, a single-crystal silicon wafer sliced out from a silicon single crystal manufactured by doping boron and a small amount of carbon like Example 2 was used. However, carbon concentration of the single-crystal silicon wafer at this time was 1 ppma.

This wafer was subjected to the ion implantation using 5×10¹³ atoms/cm² of boron at 10 keV, and then a preheating was performed at 500° C. and the flash lamp anneal using a xenon lamp as a light source was performed under conditions of irradiation energy of 22 J/cm², an irradiation time of 1.4 millisecond, and an irradiation temperature of 1200° C. Then, ion implantation defects were evaluated using the CL, and broad characteristic light emission was observed as shown in FIG. 1.

The same substrate was prepared, and p-n junctions were formed like Example 1.

An area of each p-n junction was set to 4 mm². A reverse direction leakage current value measured at each p-n junction was 200 pA.

On the levels of Examples 1 and 2 each having the carbon concentration of 0.5 ppma or less, the light emission other than the TO line caused due to the band edge emission of the silicon is not observed in the ion implantation defect evaluation using the CL, and the leakage current at the p-n junctions is small, but on the level of Comparative Example 1 having the carbon concentration of 1 ppma, the broad characteristic light emission is observed in the ion implantation defect evaluation using the CL, and it can be understood that the leakage current at the p-n junctions is large.

Thus, it can be understood that using the substrate having the carbon concentration of 0.5 ppma or less enables surely preventing the ion implantation defects on the semiconductor substrate surface formed at the time of formation of the p-n junctions from remaining when the flash lamp anneal is used as anneal after ion implantation, the leakage current value at the p-n junctions can be suppressed, and a high yield rate can be provided.

It is to be noted that the present invention is not restricted to the foregoing embodiment. The foregoing embodiment is an illustrative example, and any example which has substantially the same configuration and exerts the same functions and effects as the technical concept described in claims of the present invention is included in the technical scope of the present invention.

1-7. (canceled)

8. A semiconductor substrate for flash lamp anneal which is used in a manufacturing process of performing ion implantation to form a p-n junction on a semiconductor substrate surface and recovering an ion implantation defect by the flash lamp anneal, wherein carbon concentration of the semiconductor substrate is 0.5 ppma or less.

9. The semiconductor substrate for flash lamp anneal according to claim 8,
wherein the semiconductor substrate is made of silicon.

10. A semiconductor device, wherein the semiconductor device is fabricated with the use of the semiconductor substrate for flash lamp anneal according to claim 8.

11. A semiconductor device, wherein the semiconductor device is fabricated with the use of the semiconductor substrate for flash lamp anneal according to claim 9.

12. An anneal substrate in which a p-n junction is formed on a semiconductor substrate surface by performing ion implantation, and an ion implantation defect is recovered by flash lamp anneal,
wherein the anneal substrate has the p-n junction on the substrate surface and carbon concentration of 0.5 ppma or less.

13. The anneal substrate according to claim 12,
wherein the anneal substrate is made of silicon.

14. A semiconductor device, wherein the semiconductor device is fabricated with the use of the anneal substrate according to claim 12.

15. A semiconductor device, wherein the semiconductor device is fabricated with the use of the anneal substrate according to claim 13.

16. A method for manufacturing a semiconductor device comprising a process of forming a p-n junction on a semiconductor substrate surface, which is a process of performing ion implantation and then performing flash lamp anneal to recover an ion implantation defect,
wherein the anneal is performed with the use of a semiconductor substrate having carbon concentration of 0.5 ppma or less.
